(19) United States
(12) Patent Application Publication
(10) Pub. No.: US 2005/0024528 A1
(43) Pub. Date: Feb. 3, 2005

(54) Digital camera and a method of assembling the same

(75) Inventor: Yuichi Kurosawa, Tokyo (JP)

Correspondence Address: GREENBLUM & BERNSTEIN, P.L.C., 1950 ROLAND CLARKE PLACE, RESTON, VA, 20191, US

(73) Assignee: PENTAX Corporation, Tokyo (JP)

(21) Appl. No.: 10/900,153

(22) Filed: Jul. 28, 2004

(30) Foreign Application Priority Data
Jul. 29, 2003 (JP) 2003-281570

(51) Int. Cl. H04N 5/225; H01L 25/00

(52) U.S. Cl. 348/375

(57) ABSTRACT

A digital camera includes an image sensor unit which is fixed to a camera body, the image sensor unit incorporating an image sensor package including an image sensor, and a reference plate which serves as a positional reference when fixed to the camera body, the image sensor package being mounted to the reference plate; and supports formed on one of an internal member, of the camera body to which the reference plate is fixed, and the reference plate. Contacting surfaces of the supports, with which the reference plate is in contact when fixed to the supports, are ground to offset a positional error of the image sensor in the image sensor package so that an imaging surface of the image sensor lies in a focal plane, on which an object image is focused through a photographing optical system of the digital camera.

### BACKGROUND OF THE INVENTION

1. Field of the Invention

The present invention relates to a digital camera having an image pick-up device such as a CCD image sensor. More specifically, the present invention relates to such a digital camera which includes an improved structure fixing the image pick-up device that is to be included in a camera body of the digital camera, and further relates to a method of assembling the same digital camera.

2. Description of the Related Art

A CCD image sensor is widely used as an image pick-up device (image sensor) of a digital camera. This type of CCD image sensor is usually provided in the form of a CCD package (image sensor package), and this CCD package is included in a camera body, mounted thereto. The CCD package is constructed so that a CCD chip (CCD image sensor) is fixed to a package base by adhesive or solder and so that the CCD chip is electrically connected to external leads provided on the package base. A protection glass plate is fixed to the front of the package base to seal the CCD chip between the protection glass plate and the package base. The CCD package which is structured in such a manner is installed at a position (image forming position) inside the camera body in the vicinity of the rear surface thereof where an image is formed through a photographing optical system. It is generally the case that the CCD package, together with a low-pass filter and other components which are to be positioned in front of the CCD image sensor, is mounted to a reference plate to constitute a CCD unit (image sensor unit) and that this CCD unit is fixed to the camera body via the reference plate. Additionally, a light receiving surface (imaging surface) of the CCD chip is oriented to be orthogonal to the optical axis of the photographing optical system at a position of an image plane, on which an image is formed through a photographing optical system, usually at a focal point of the photographing optical system.

Such a conventional type of CCD unit is made by fixing a rear surface of the package base of the CCD package closely to a front surface (fixing surface) of the reference plate by, for example, an adhesive, when the CCD package is mounted to the reference plate. Fixing the reference plate of this CCD unit to a camera body at a given position thereon makes it possible for the reference plate to be installed with the reference plate being orthogonal to the optical axis of the photographing optical system, and makes it possible for the imaging surface of the CCD chip to be positioned orthogonal to the optical axis of the photographing optical system at a focal point thereon, and further makes it possible to determine the focal point.

However, it is often the case that adhesive or solder by which the CCD chip is fixed to the package base is not evenly coated on the package base. Accordingly, a CCD package in which the CCD chip is bonded to the package base with the imaging surface of the CCD chip not being precisely parallel to the package base is often produced. Therefore, even if the CCD package is bonded to the reference plate of the CCD unit, the CCD unit in which the imaging surface of the CCD chip is precisely parallel to the reference plate cannot be obtained. Consequently, the imaging surface of the CCD chip cannot be oriented in a position precisely orthogonal to the optical axis of the photographing optical system, so that the imaging surface of the CCD chip is slightly inclined to the focal plane. Moreover, the focal point does not coincide with the imaging surface of the CCD chip.

In a digital camera using a small-format CCD image sensor as a CCD chip incorporated in the CCD package, in which the diagonal size of the imaging surface of the CCD chip is equal to or smaller than ½ inch, the aperture of an imaging lens is small so as to correspond to the diagonal size of the imaging surface of the CCD chip while the imaging angle on the imaging surface with respect to the optical axis of the imaging lens is small. In contrast to such a digital camera, in a digital camera using a large-format CCD image sensor as a CCD chip incorporated in the CCD package, in which the diagonal size of the imaging surface of the CCD chip is equal to or greater than 4/3 inches, the aperture of an imaging lens is large and the imaging angle on the imaging surface with respect to the optical axis of the imaging lens is large. Accordingly, the depth of focus in the case of using the large-format CCD image sensor is narrower than the depth of focus in the case of using the small-format CCD image sensor. Therefore, if the CCD package is fixed to a camera body with the imaging surface of the CCD chip being slightly inclined to a plane orthogonal to the optical axis of a photographing optical system, an image that is formed on a periphery of the imaging surface, a deviation of which from a focal plane in the optical axis direction is greater than a deviation of a central portion of the imaging surface from the focal plane in the optical axis direction, easily becomes out-of-focus (blurred); the amount of defocus becomes conspicuous specifically in the case of using the large-format CCD image sensor, in which the deviation in the optical axis direction in the periphery of the imaging surface becomes great. Accordingly, in the case of using the large-format CCD image sensor, a positional deviation of the imaging surface cannot be tolerated in the depth of field of a photographing lens.

As can be understood from the above description, a conventional CCD unit is not always constructed so that the imaging surface of the CCD chip is precisely parallel to the reference plate. Therefore, a structure for positioning the imaging surface of the CCD chip so that the imaging surface becomes orthogonal to the photographing optical axis is required when the CCD unit is fixed to a camera body. For instance, a structure fixing the CCD unit to a camera body has been proposed in Japanese Unexamined Patent Publication 2003-69886. According to this fixing structure, a camera body is provided with a plurality of screw holes, a corresponding plurality of adjusting cylindrical members are respectively screwed into the plurality of screw holes, and a reference plate of the CCD unit is fixed to the plurality of adjusting cylindrical members by set screws with the reference plate contacting with end surfaces of the plurality of adjusting cylindrical members. This fixing structure makes it possible to adjust the inclination of the reference plate so that the imaging surface of the CCD chip becomes precisely orthogonal to the photographing optical axis by varying the height (axial position) of the end surface of each adjusting cylindrical member by changing the rotational position of each adjusting cylindrical member while viewing the image captured by the imaging surface of the CCD chip.

Providing a camera body with such a conventional fixing structure increases the number of elements of a camera, and also requires that an adjusting operation be performed in which the aforementioned plurality of adjusting cylindrical members are adjusted while it is visually checked whether the imaging surface of the CCD chip is directed toward a predetermined direction when the CCD unit is installed in the camera body. Accordingly, the aforementioned conventional fixing structure complicates the operation installing the CCD unit in a camera body, which is in need of improvement.

### SUMMARY OF THE INVENTION

The present invention provides a digital camera using an image pick-up device, wherein the digital camera has a structure making it possible for the image pick-up device to be installed in a camera body in a state where the imaging surface of the image pick-up device is precisely positioned with respect to a focal plane that is orthogonal to the optical axis of a photographing lens. The present invention further provides a method of assembling the same digital camera.

According to the present invention, a digital camera is provided, including an image sensor unit which is fixed to a camera body, the image sensor unit incorporating an image sensor package including an image sensor, and a reference plate which serves as a positional reference when fixed to the camera body, the image sensor package being mounted to the reference plate; and supports formed on one of an internal member, of the camera body to which the reference plate is fixed, and the reference plate. Contacting surfaces of the supports, with which the reference plate is in contact when fixed to the supports, are ground to offset a positional error of the image sensor in the image sensor package so that an imaging surface of the image sensor lies in a focal plane, on which an object image is focused through a photographing optical system of the digital camera.

It is desirable for the image sensor package to be bonded to the reference plate.

It is desirable for the contacting surfaces of the supports are ground to lie in a plane inclined with respect to an optical axis of the photographing optical system in a first inclination direction by an angle of inclination identical to an angle of inclination of the imaging surface with respect to the optical axis in a second inclination direction opposite to the first inclination direction.

It is desirable for the supports to be bosses, respectively, which are integrally formed with one of a main frame serving as the internal member and the reference plate. The other of the main frame and the reference plate is fixed to the bosses by set screws which are screwed into the bosses.

It is desirable for the one of the main frame and the reference plate to include positioning pins which project therefrom to be respectively engaged in positioning holes which are formed on the other of the main frame and the reference plate.

It is desirable for the positional error to be measured with a microscope before the reference plate is fixed to the internal member of the camera body.

It is desirable for the main frame to have a rectangular aperture through which an object light bundle which is passed through the photographing optical system is incident on the imaging surface of the image sensor.

In another embodiment, a digital camera is provided, including a photographing lens attached to a camera body of the digital camera; a frame positioned inside the camera body and having a rectangular aperture through which an object light bundle which is passed through the photographing lens is incident on a focal plane; an image sensor unit which includes a reference plate fixed to the frame, and an image sensor package mounted to the reference plate; an image sensor provided in the image sensor package; and protrusions projecting rearward from the frame in an optical axis direction, the reference plate being fixed to end surfaces of the protrusions. The end surfaces of the protrusions are ground to lie in a plane so that an imaging surface of the image sensor lies in the focal plane.

In another embodiment, an assembling method is provided for a digital camera having an image sensor package including an image sensor; and a reference plate to which the image sensor package is mounted, the reference plate being fixed to supports formed on an internal member of the camera body with the reference plate being in contact with contacting surfaces of the supports. The assembling method including measuring an angle of inclination of an imaging surface of the image sensor with respect to the reference plate; and grinding the contacting surfaces of the supports to lie in a plane so that the plane is inclined with respect to an optical axis of a photographing lens of the digital camera in an inclination direction opposite to the direction of the inclination of the imaging surface by an angle of inclination identical to the angle of inclination of the imaging surface to make the imaging surface of the image sensor lie in a focal plane, on which an object image is focused through the photographing lens.

In the assembling method, it is desirable for the contacting surfaces to be ground so that the plane is inclined with respect to a mounting surface on the camera body, to which the photographing lens is mounted, in the inclination direction opposite to the direction of the inclination of the imaging surface by the angle of inclination identical to the angle of inclination of the imaging surface.

It is desirable for the angle of inclination of the imaging surface to be measured with a microscope before the reference plate is fixed to the internal member of the camera body.

The present disclosure relates to subject matter contained in Japanese Patent Applications Nos. 2003-281570 (filed on Jul. 29, 2003) which is expressly incorporated herein by reference in its entirety.

### BRIEF DESCRIPTION OF THE DRAWINGS

The invention will be discussed below in detail with reference to the accompanying drawings, in which:

FIG. 1 is a perspective view, with a portion broken away for clarity, of an embodiment of a digital camera according to the present invention, viewed obliquely from behind the digital camera;

FIG. 2 is an exploded perspective view of elements of the digital camera shown in FIG. 1;

FIG. 3 is an enlarged cross sectional view taken along the III-III line in FIG. 1;

FIG. 4 is a perspective view of a CCD unit, viewed obliquely from the front thereof;

FIG. 5 is an exploded perspective view of the CCD unit shown in FIG. 4;

FIG. 6A is an explanatory diagram for illustrating a process of measuring the angle of inclination of the imaging surface of a CCD chip;

FIG. 6B is an explanatory diagram for illustrating a process of grinding the contacting surface of each support boss formed on a main frame of a camera body; and

FIG. 7 is a perspective view of another embodiment of the CCD unit, seen from obliquely front thereof.

### DESCRIPTION OF THE PREFERRED EMBODIMENT

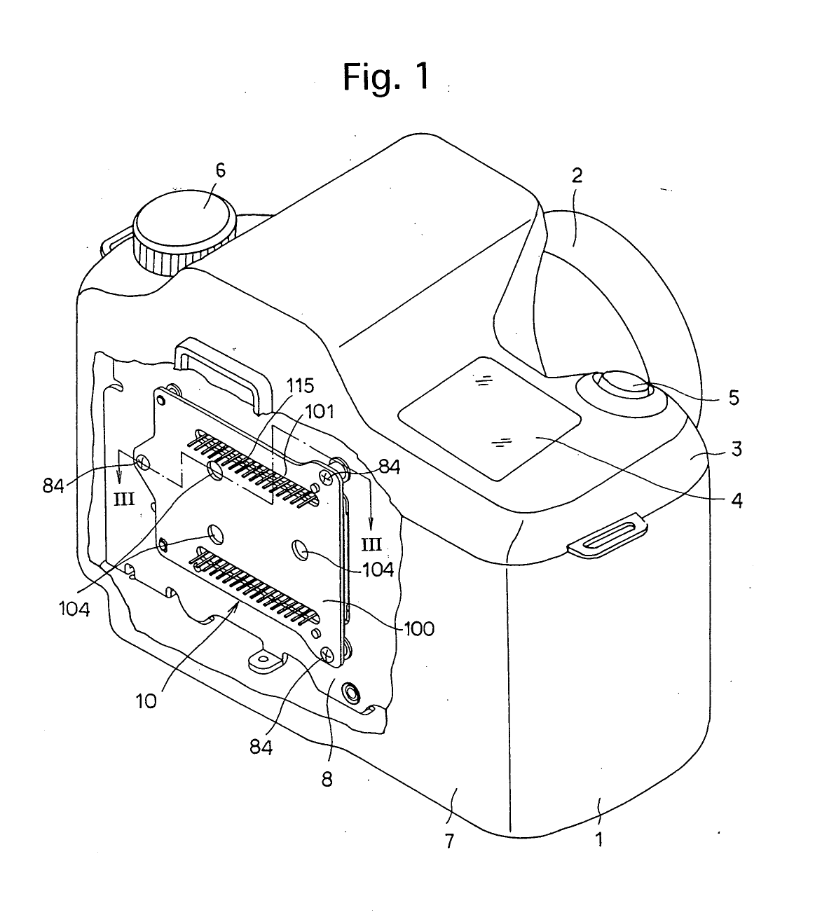

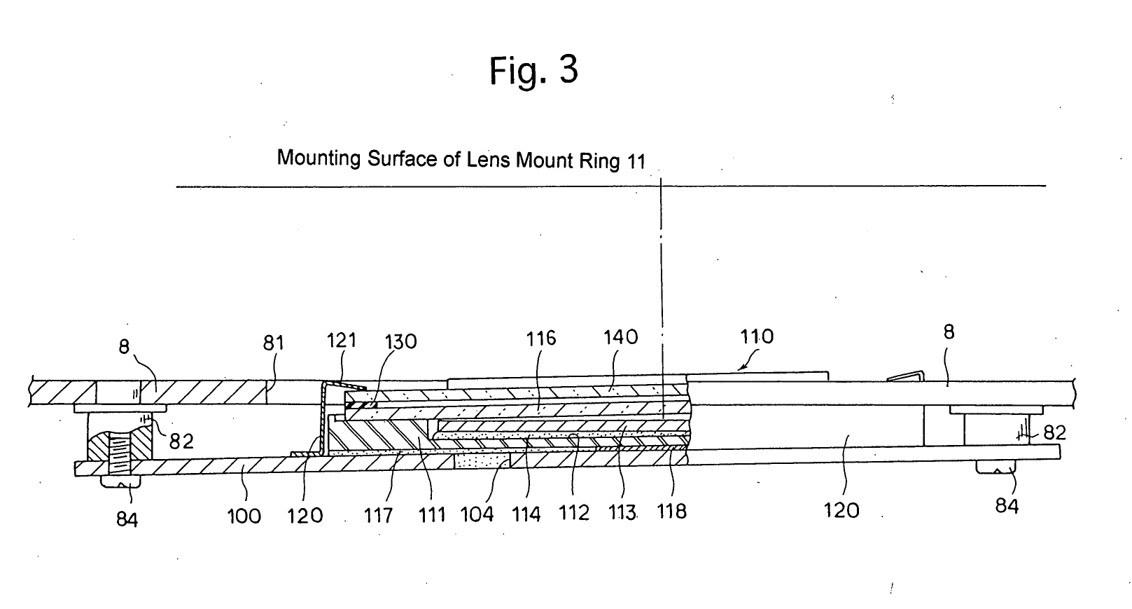

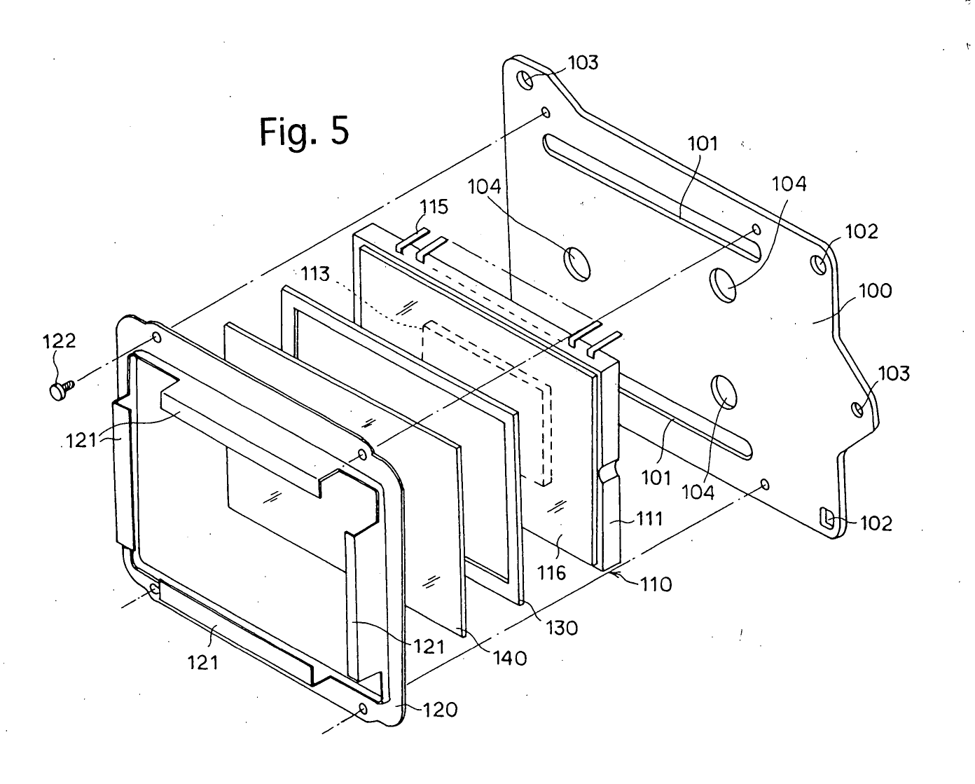

FIG. 1 shows an embodiment of a digital camera according to the present invention. The digital camera 200 that is constructed as an SLR digital camera is provided with an interchangeable photographing lens 2 which is detachably attached to the front of a camera body 1. The digital camera 200 is provided on a top cover 3 of the camera body 1 with an LCD indicating portion 4, a release button 5 and a select dial (dial switch) 6. The digital camera 200 is provided on a back cover 7, a portion of which is broken away for clarity in FIG. 1, with an LCD monitor and various switches (all of which are not shown in FIG. 1). The digital camera 200 is provided therein inside the back cover 7 (i.e., inside the camera body 1) with an image sensor unit 10. This image sensor unit 10 will be hereinafter referred to as a CCD unit 10 since the digital camera 200 uses a CCD image sensor as an image pick-up device. The CCD unit 10 is fixed to a main frame (internal member of the camera body 1) 8 positioned inside the camera body 1 in an internal space thereof behind a mirror box (not shown) provided in the camera body 1 so that an imaging surface of a CCD chip (image sensor) 113 (see FIGS. 3 and 5) lies in a focal plane on which an object image is formed through the photographing lens 2.

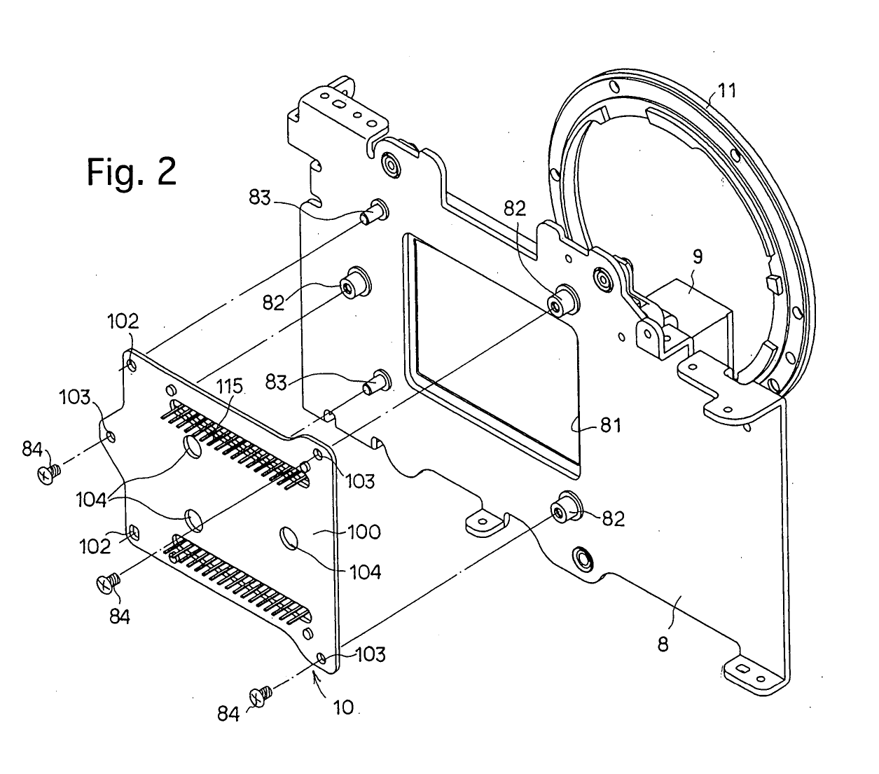

FIG. 2 is an exploded perspective view of elements of the digital camera 200, and FIG. 3 is an enlarged cross sectional view taken along III-III line in FIG. 1. As shown in FIG. 2, the digital camera 200 is provided in front of the main frame 8 with a shutter unit 9, and is provided, in front of the mirror box (not shown) that accommodates the shutter unit 9, with a lens mount ring (lens mount) 11 to which the photographing lens 2 is detachably attached. The lens mount ring 11 is fixed to a front surface of the camera body 1 to be supported thereby. The main frame 8 is made out of a solid metal plate, and is provided with a rectangular aperture 81 through which the CCD unit 10 is communicatively connected with the mirror box so that a light bundle of an object image which is formed through the photographing optical system 2 passes through the rectangular aperture 81 to be focused on the imaging surface of the CCD unit 10. Accordingly, the CCD unit 10 is fixed to the main frame 8 at a position facing the rectangular aperture 81.

The main frame 8 is provided on a rear surface thereof around the rectangular aperture 81 with three cylindrical support bosses 82 each of which is integrally fixed to the main frame 8 by swaging. A reference plate (base plate) 100 which is provided as an element of the CCD unit 10 is in contact with an end surface (contacting surface) of each support boss 82, and three set screws 84 are respectively screwed into the three cylindrical support bosses 82 to fix the CCD unit 10 to the main frame 8. Two narrow cylindrical positioning pins 83 project rearward from a rear surface of the main frame 8 at upper and lower positions thereon in the vicinity of upper and lower ends of a side edge (left side edge as viewed in FIG. 2) of the rectangular aperture 81, respectively. Each positioning pin 83 is integrally fixed to the main frame by swaging. Although being discussed in detail later, the positioning pins 83 are respectively engaged in two positioning holes 102 of the CCD unit 10 to position the CCD unit 10 precisely with respect to the main frame 8.

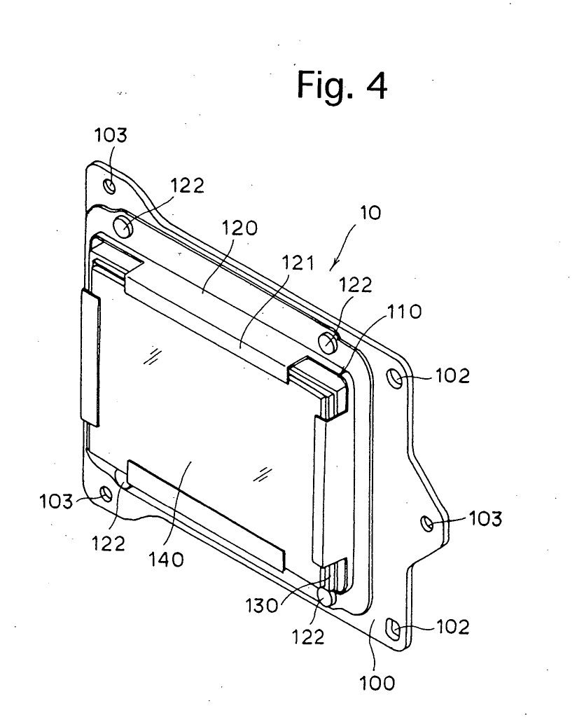

As shown in the perspective view and the exploded perspective view in FIGS. 4 and 5, respectively, the CCD unit 10 is includes a holding frame (holding member) 120 provided as a separate member from the reference plate 100, and a CCD package (image sensor package) 110 which is bonded to the reference plate 100. The CCD package 110 is supplied as a package produced in a factory. As can be seen in FIG. 3, the CCD package 110 is provided with a package base 111 made of a material such as ceramics or resin. The package base 111 is provided on a surface thereof with a mounting recess 112 in which the CCD chip 113 is positioned. The CCD chip 113 is mounted and bonded to a bottom surface of the mounting recess 112 by a bonding agent 114 such as an adhesive or a low-melting solder. If the bonding agent 114 is solidified so as to have an uneven thickness, the imaging surface of the CCD chip 113 cannot be positioned to be precisely parallel to a surface of the package base 111 as noted above. FIG. 3 shows a case where the CCD chip 113 is bonded to the package base 111 with the imaging surface of the CCD chip 113 being slightly inclined to the surface of the package base 111 due to an uneven thickness of the bonding agent 114. Although not shown in the drawings, electrodes of the CCD chip 113 are electrically connected to two external lead arrays 115 which extend from the package base 111 via an internal wiring system (not shown). The CCD chip 113 is sealed with a projection grass 116 which is bonded to a front surface of the package base 111.

On the other hand, the reference plate 100 is made out of a metal plate having an even thickness, and is provided with two slots 101 in which the two external lead arrays 115 of the CCD package 110 are insertable, respectively. A rear surface of the CCD package 110 is bonded to a front surface (mounting surface) of the reference plate 100 by an adhesive 117 with the two external lead arrays 115 inserted into the two slots 101, respectively. An instantaneous adhesive that solidifies in an extremely short period of time is used as the adhesive 117 in this particular embodiment of the digital camera 200. The reference plate 100 is provided at three points on a rear surface of the reference plate 100 with three adhesive injection holes 104 so that the adhesive 117 can be injected into each of the three adhesive injection holes 104, which are open on the rear surface of the reference plate 100, fill in a gap between a front surface of the reference plate 100 and a rear surface of the CCD package 110 (i.e., a rear surface of the package base 111) to bond the CCD package 110 to the reference plate 100 in a state where the CCD package 110 is mounted to the reference plate 100. If an adhesive which solidifies in a relatively long period of time is used as the adhesive 117, the CCD package 110 can be bonded to the reference plate 100 after an adhesive is applied to a rear surface of the CCD package 110. The reference plate 100 is provided, on a surface thereof other than the surface of the reference plate 100 to which the CCD package 110 is bonded, with the two positioning holes 102 which are formed to correspond to the positions of the two positioning pins 83, respectively, that project from the main frame 8.

The holding frame 120 is fixed to a front surface of the reference plate 100 that is constructed in the above described manner. The holding frame 120 is fixed to the reference plate 100 by four set screws 122 (only one of them is shown in FIG. 5) which extend through the holding frame 120 at four different points on the periphery of the holding frame 120. The holding frame 120 is made of a resilient metal plate which is shaped into a rectangular frame. The holding frame 120 is provided on four sides thereof with four holding leaves 121, each of which is formed by bending a portion of the holding frame 120. In addition, the present embodiment of the CCD package 110 is provided on a front surface of the protection glass 116 with a dust-resistant sealing member 130 having a rectangular frame shape, and is provided on the dust-resistant sealing member 130 with a rectangular low-pass filter (LPF) 140 having dimensions substantially identical to the dimensions of the protection glass 116. The resiliency of the four holding leaves 121 of the holding frame 120 causes the low-pass filter 140 to be pressed against a front surface of the protection glass 116 via the dust-resistant sealing member 130, and simultaneously presses the low-pass filter 140 and the dust-resistant sealing member 130 against the reference plate 100 to hold the low-pass filter 140 and the dust-resistant sealing member 130 to the reference plate 100.

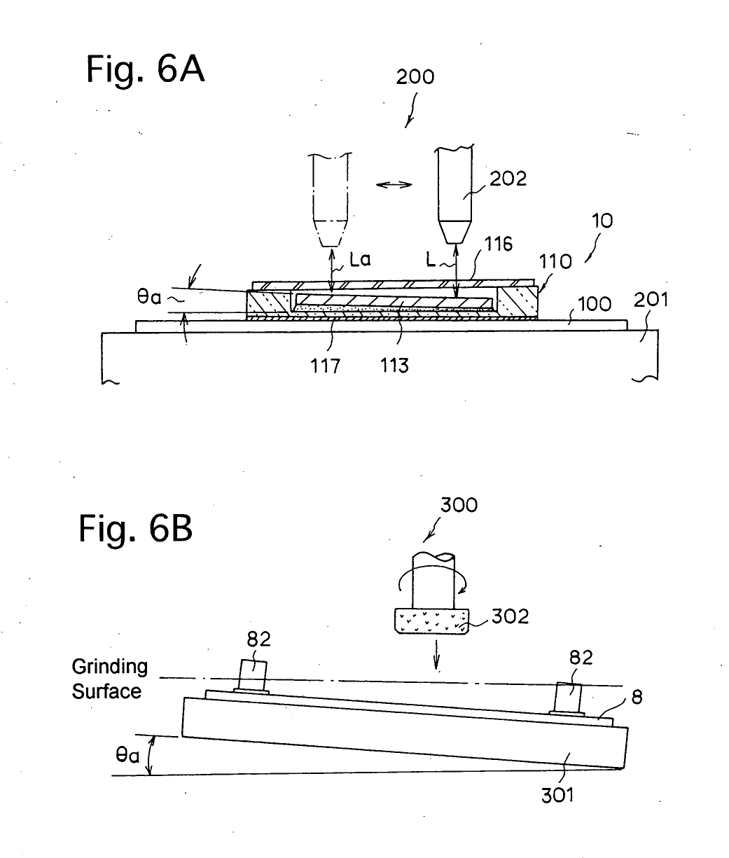

A method of assembling the CCD unit 10 that has the above described structure will be hereinafter discussed. Firstly, the angle of inclination of the imaging surface of the CCD chip 113 is measured in a state where the CCD package 110 has been bonded to the reference plate 100. This measurement is carried out by mounting the reference plate 100 on a stage 201 of an optical measuring microscope 200 and placed on a plane orthogonal to an optical axis of a microscopic optical system 202 as shown in FIG. 6A. Subsequently, the optical measuring microscope 200 is operated so as to be focused on the imaging surface of the CCD chip 113, and subsequently, either the stage 201 or the microscopic optical system 202 is moved in X-direction and Y-direction in the aforementioned plane orthogonal to the optical axis of the optical measuring microscope 200. In the illustrated. embodiment shown in FIG. 6A, the microscopic optical system 202 is moved in X-direction and Y-direction relative to the stage 201. During this movement of the microscopic optical system 202, a distance L between the microscopic optical system 202 and the imaging surface of the CCD chip 113 in the optical axis direction of the microscopic optical system 202 (vertical direction as viewed in FIG. 6A) remains invariant while an in-focus state of the optical measuring microscope 200 is ensured at any X-Y point on the imaging surface of the CCD chip 113 if the imaging surface of the CCD chip 113 is positioned precisely parallel to the reference plate 100. On the other hand, in the case where the optical measuring microscope 200 is out-of-focus on a portion of the imaging surface of the CCD chip 113 to cause a blurry image thereat, the optical measuring microscope 200 is operated to bring the microscopic optical system 202 into an in-focus state at that portion, and thereupon a distance La between the microscopic optical system 202 and the imaging surface of the CCD chip 113 in the optical axis direction of the microscopic optical system 202 is measured and stored in a memory (not shown). The same distance measuring operation is repeated at not less than three different points (desirably, at least four different points) on the imaging surface of the CCD chip 113. With this distance data stored in the memory, an angle of inclination θa of the imaging surface of the CCD chip 113 with respect to the reference plate 100 in three-dimensional direction of the imaging surface of the CCD chip 113 can be determined.

Subsequently, as shown in FIG. 6B, the main frame 8 is mounted on a carriage 301 of a milling machine 300 with the rear surface of the main frame 8 facing upward, and then the carriage 301 is tilted three-dimensionally by an angle of inclination identical to the aforementioned angle of inclination θa of the imaging surface of the CCD chip 113, which has been measured in the previous angle-measuring process. Subsequently, the end surface of each of the three support bosses 82 is ground by a rotary milling head (grinding wheel) 302 so that the end surfaces of the three cylindrical support bosses 82 (which serve as contacting surfaces to be in contact with the reference plate 100 of the CCD unit 10) are formed to lie in a plane extending along the horizontal direction of the milling machine 300, i.e., in a plane orthogonal to the axis of rotation of the milling machine 300. Note that this process has been discussed assuming that the main frame 8 is positioned to be parallel to the mounting surface of the lens mount ring 11. However, in the case where this assumption is not ensured, it is possible to firstly fix the main frame 8 to the camera body 1, subsequently to mount this camera body on the carriage 301 of the milling machine 300 with the lens mount ring 11 facing downward, and subsequently to grind the end surfaces (contacting surfaces) of the three cylindrical support bosses 82 which project upward from the main frame 8 with the rotary milling head 302. In this case, the end surface of each support boss 82 is ground to become a flat surface lying at a position away from the mounting surface of the lens mount ring 11 by a predetermined distance in an optical axis O (see FIG. 3) of the CCD chip 113 (which is coincident with the optical axis of the photographing lens 2).

After the completion of the operation of grinding the end surface of each support boss 82, the CCD unit 10 is fixed to the main frame 8. The position of the CCD unit 10 on a rear flat surface of the main frame 8 is determined by fitting each of the two positioning holes 102 on the associated positioning pin 83 of the main frame 8. Subsequently, the reference plate 100 is fixed to the main frame 8 by screwing the three set screws 84 into the three cylindrical support bosses 82, respectively, with the end surface of each support boss 82 being in contact with the front surface of the reference plate 100 to thereby fix the CCD unit 10 to the main frame 8. Since the plane in which the end surfaces of the three support bosses 82 lie is inclined to the mounting surface of the lens mount ring 11 as noted above, and since the angle of this inclination of this plane in a first inclination direction is identical to the angle of inclination of the imaging surface of the CCD chip 113 with respect to the reference plane 100 in the CCD unit 10 in a second inclination direction opposite to the aforementioned first inclination direction, the reference plate 100 fixed to the main frame 8 is not parallel to neither the main frame 8 nor the mounting surface of the lens mount ring 11. However, the imaging surface of the CCD chip 113 is parallel to the mounting surface of the lens mount ring 11, and the imaging surface of the CCD chip 113 is positioned orthogonal to the optical axis of the photographing lens 2 at a focal point thereon.

Grinding the contacting surfaces of the three support bosses 82 of the main frame 8 so that the angle of inclination of the plane, in which the contacting surfaces of the three support bosses 82 lie in one inclination direction (first inclination direction) becomes identical to the angle of inclination of the imaging surface of the CCD chip 113 in the inclination direction opposite to the first inclination direction, in a manner such as described above makes it possible for the imaging surface of the CCD chip 113 to be precisely positioned parallel to the mounting surface of the lens mount ring 11. Accordingly, the imaging surface of the CCD chip 113 can be precisely positioned to lie in a focal plane of the photographing lens 2 in the optical axis direction thereof by simply fixing the reference plate 100 to the three support bosses 82 by screwing the three set screws 84 into the three support bosses 82 in the operation fixing the CCD unit 10 to the camera body 1, which considerably facilitates the fixing operation of the CCD unit 10 to the main frame 8.

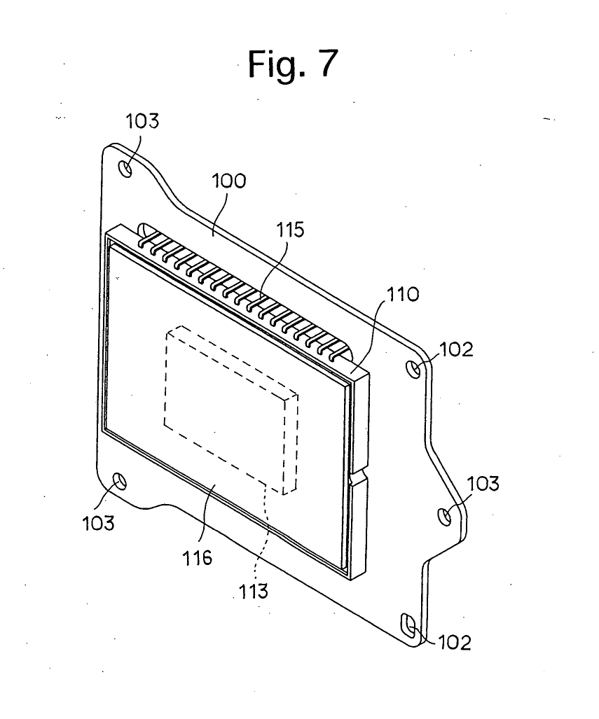

In the above illustrated embodiment of the digital camera 200, dust can be reliably prevented from being deposited on the front surface of the protection glass 116 of the CCD package 110, especially on an area immediately in front of the imaging surface of the CCD chip 113 since the low-pass filter 140 is incorporated into the CCD unit 10 and because the dust-resistant sealing member 130 is held between the low-pass filter 140 and the CCD package 110. If no low-pass filter such as the low-pass filter 140 is incorporated into the CCD unit 10, the structure of the CCD unit 10 is extremely simple as shown in FIG. 7 in which the CCD package 110 is bonded to a front surface of the reference plate 100. In this case there is a possibility of dust being deposited on the front surface of the projection glass 116 of the CCD package 110 when the CCD unit 10 is fixed to the main frame 8, so that it will be necessary for the CCD unit 10 to be fixed to the main frame 8 in a clean room, which more or less increases the number of processes or operations fixing to the CCD package to the main frame 8. Furthermore, in an arrangement in which a dust-resistant sealing member is installed between the main frame 8 and the reference plate 100, there is a possibility of dust intruding into the space immediately in front of the reference plate 100 through the two slots 101 thereof, into which the two external lead arrays 115 are inserted, and being deposited on the front surface of the projection glass 116.

It is desirable that an instantaneous adhesive that solidifies in an extremely short period of time be used as the adhesive 117, which is used to bond the CCD package 110 to the reference plate 100. In addition, if an adhesive having a high degree of thermal conductivity is used as the adhesive 117, the heat produced by the CCD chip 113 can be transferred to the reference plate 100 efficiently via the adhesive 117 and can be dissipated from the adhesive 117, which improves the cooling efficiency of the CCD chip 113, thus effectively reducing thermal noise of the CCD chip 113. In the case where it is difficult to adopt an adhesive having a high degree of thermal conductivity, a heat dissipation grease 118 having a high degree of thermal conductivity can be applied to a portion of the rear surface of the package base 111 of the CCD package 110 as shown in FIG. 3 (i.e., on an area of the package base 111 immediately behind the CCD chip 113). In this case, the heat produced by the CCD chip 113 can be dissipated from the reference plate 100 via the heat dissipation grease 118.

The image pick-up device incorporated in a digital camera according to the present invention is not limited solely to a CCD image sensor; the present invention can be applied to any digital cameras using an image sensor package having a structure wherein the imaging surface of the image pick-up device is not necessarily ensured to be parallel to the reference plate with a high degree of precision.

According to the present invention, the angle of the inclination of the imaging surface of the image sensor with respect to the reference plate in the first inclination direction and the angle of inclination of the plane, in which the contacting surfaces of the supports lie, with respect to the reference plate in the second inclination direction that is opposite to the first inclination direction become identical to each other since firstly the angle of inclination of the imaging surface of the image sensor with respect to the reference plate in the image sensor unit is measured, secondly the contacting surfaces of the supports are ground so that the aforementioned plane is inclined to the optical axis by an angle of inclination identical to the angle of inclination of the imaging surface of the image sensor, and thirdly the reference plate is fixed to the supports to be supported thereby. Accordingly, by simply fixing the reference plate to the supports, the inclination of the imaging surface of the image sensor can be offset by the inclination of the plane in which the contacting surfaces of the supports lie, so that the imaging surface of the image sensor can be set to lie in a focal plane that is orthogonal to the optical axis. Consequently, the structure for fixing the image sensor unit to the camera body can be simplified, while the operation for installing the image sensor unit into the camera body can be improved; moreover, the workability of assembling the digital camera can be improved.

Obvious changes may be made in the specific embodiments of the present invention described herein, such modifications being within the spirit and scope of the invention claimed. It is indicated that all matter contained herein is illustrative and does not limit the scope of the present invention.

1. A digital camera comprising:
an image sensor unit which is fixed to a camera body, said image sensor unit incorporating an image sensor package including an image sensor, and a reference plate which serves as a positional reference when fixed to said camera body, said image sensor package being mounted to said reference plate; and
supports formed on one of an internal member, of said camera body to which said reference plate is fixed, and said reference plate;
wherein contacting surfaces of said supports, with which said reference plate is in contact when fixed to said supports, are ground to offset a positional error of said image sensor in said image sensor package so that an imaging surface of said image sensor lies in a focal plane, on which an object image is focused through a photographing optical system of said digital camera.

2. The digital camera according to claim 1, wherein said image sensor package is bonded to said reference plate.

3. The digital camera according to claim 1, wherein said contacting surfaces of said supports are ground to lie in a plane inclined with respect to an optical axis of said photographing optical system in a first inclination direction by an angle of inclination identical to an angle of inclination of said imaging surface with respect to said optical axis in a second inclination direction opposite to said first inclination direction.

4. The digital camera according to claim 1, wherein said supports comprise bosses, respectively, which are integrally formed with one of a main frame serving as said internal member and said reference plate,
wherein the other of said main frame and said reference plate is fixed to said bosses by set screws which are screwed into said bosses.

5. The digital camera according to claim 4, wherein said one of said main frame and said reference plate comprises positioning pins which project therefrom to be respectively engaged in positioning holes which are formed on said other of said main frame and said reference plate.

6. The digital camera according to claim 1, wherein said positional error is measured with a microscope before said reference plate is fixed to said internal member of said camera body.

7. The digital camera according to claim 4, wherein said main frame has a rectangular aperture through which an object light bundle which is passed through said photographing optical system is incident on said imaging surface of said image sensor.

8. A digital camera comprising:
a photographing lens attached to a camera body of said digital camera;
a frame positioned inside said camera body and having a rectangular aperture through which an object light bundle which is passed through said photographing lens is incident on a focal plane;
an image sensor unit which includes a reference plate fixed to said frame, and an image sensor package mounted to said reference plate;
an image sensor provided in said image sensor package; and
protrusions projecting rearward from said frame in an optical axis direction, said reference plate being fixed to end surfaces of said protrusions,
wherein said end surfaces of said protrusions are ground to lie in a plane so that an imaging surface of said image sensor lies in said focal plane.

9. A assembling method for a digital camera having an image sensor package including an image sensor; and a reference plate to which said image sensor package is mounted, said reference plate being fixed to supports formed on an internal member of said camera body with said reference plate being in contact with contacting surfaces of said supports, said assembling method comprising:
measuring an angle of inclination of an imaging surface of said image sensor with respect to said reference plate; and
grinding said contacting surfaces of said supports to lie in a plane so that said plane is inclined with respect to an optical axis of a photographing lens of said digital camera in an inclination direction opposite to the direction of said inclination of said imaging surface by an angle of inclination identical to said angle of inclination of said imaging surface to make said imaging surface of said image sensor lie in a focal plane, on which an object image is focused through said photographing lens.

10. The assembling method according to claim 9, wherein said contacting surfaces are ground so that said plane is inclined with respect to a mounting surface on said camera body, to which said photographing lens is mounted, in said inclination direction opposite to said direction of said inclination of said imaging surface by said angle of inclination identical to said angle of inclination of said imaging surface.

11. The assembling method according to claim 9, wherein said angle of inclination of said imaging surface is measured with a microscope before said reference plate is fixed to said internal member of said camera body.
